(19) United States
(12) Patent Application Publication
(10) Pub. No.: US 2025/0377790 A1
(43) Pub. Date: Dec. 11, 2025

(54) DETERMINING READ VOLTAGE BASED ON TEMPERATURE OF A NON-VOLATILE MEMORY DEVICE

(71) Applicant: Microchip Technology Incorporated, Chandler, AZ (US)

(72) Inventors: Pitamber SHUKLA, San Jose, CA (US); Saswati DAS, Milpitas, CA (US); Srinivas YELISETTI, Fremont, CA (US); Nian Niles YANG, Mountain View, CA (US)

(21) Appl. No.: 18/964,434

(22) Filed: Nov. 30, 2024

Related U.S. Application Data
(60) Provisional application No. 63/657,119, filed on Jun. 6, 2024.

(51) Int. Cl. G06F 3/06; G11C 16/04; G11C 16/26

(52) U.S. Cl. CPC G06F 3/0611; G06F 3/0653; G06F 3/0659; G06F 3/0679; G11C 16/26; G11C 16/0483

(57) ABSTRACT

In some implementations, a controller may receive, from a host device, a read command to access data stored on a non-volatile memory device. The controller may determine a read voltage based on a temperature associated with the non-volatile memory device. The controller may perform, based on the read command, a read operation using the read voltage to access the data. The controller may provide the data to the host device.

### RELATED APPLICATION

This application claims priority to U.S. Provisional Patent Application No. 63/657,119 entitled “DETERMINING READ VOLTAGE BASED ON TEMPERATURE OF A NON-VOLATILE MEMORY DEVICE,” filed Jun. 6, 2024, which is incorporated herein by reference in its entirety.

### FIELD

The present disclosure generally relates to performing read operation on a storage device, such as a non-volatile memory device.

### BACKGROUND

A non-volatile memory device may include a storage device (e.g., a memory device) that may store and retain data without external power supply. One example of a non-volatile memory device is a not-and (NAND) flash memory device. The non-volatile memory device may be included in a solid state device (SSD). A controller, included in the SSD, may perform different operations of the non-volatile memory device. The different operations may include a read operation, a write operation, and an erase operation, without limitation.

### SUMMARY

In some implementations, a method may comprise receiving, from a host device, a read command to access data stored on a non-volatile memory device; determining a read voltage based on a temperature associated with the non-volatile memory device; performing, based on the read command, a read operation using the read voltage to access the data; and providing the data to the host device.

In some implementations, a system may comprise a controller, of a non-volatile memory device, to: determine a temperature associated with the non-volatile memory device; determine, based on the temperature, a read voltage for accessing data stored by the non-volatile memory device; and perform a read operation, using the read voltage, to access the data.

In some implementations, a computer program product may comprise one or more computer readable storage media, and program instructions collectively stored on the one or more computer readable storage media, the program instructions comprising: program instructions to determine a temperature associated with a non-volatile memory device when a portion of the non-volatile memory device was written; program instructions to determine, based on the temperature, a read voltage for accessing data stored by the non-volatile memory device; and program instructions to perform a read operation, using the read voltage, to access the data.

### BRIEF DESCRIPTION OF THE DRAWINGS

FIG. 1 is a diagram of an example of dynamic read voltage adjustment for a virtual block described herein.

FIG. 2 is a diagram of using a dynamic read voltage for a virtual block described herein.

FIG. 3 is a diagram of an example of dynamic read voltage adjustment for a virtual block based on a cross temperature described herein.

FIG. 4 is a diagram of an example of a device generating logical to physical (L2P) addresses described herein.

FIG. 5 is a diagram of example components of one or more devices of FIG. 4.

FIG. 6 is a flowchart of example processes associated with dynamic read voltage adjustment for a virtual block described herein.

### DETAILED DESCRIPTION

The following detailed description of example implementations refers to the accompanying drawings. The same reference numbers in different drawings may identify the same or similar elements.

To access data stored on a non-volatile memory device, a host device may provide a read command. The non-volatile memory device may be included on a solid-state device (SSD) along with a controller. Based on the read command, the controller may cause a read operation to be performed on a memory block (or “block”) of the non-volatile memory device. A block may refer to a physical location of the non-volatile memory device (e.g., a particular memory cell, a particular set of memory cells, or other suitable type of addressable physical element of the non-volatile memory device). Thus, a read operation may include reading data stored in a physical location of the non-volatile memory device. The read operation may be performed using read voltages (e.g., threshold voltages that are used to perform read operations). Read voltages may include “default” read voltages that are set by a manufacturer of the non-volatile memory device.

In some situations, the block may be subjected to conditions or events that cause unpredictable conditions that affect the ability to access data stored on the block, such as a migration of electrons stored in one or more memory cells in the physical location. Such conditions or events may include, for example, the block being subjected to an increase in temperature, to program/erase cycles, or to other types of conditions or events, which may ultimately degrade the data retention and reliability of the block. Degradation of data retention may cause read errors when performing read operations using the default threshold voltages. The read errors may include, for example, receiving or determining erroneous values or data from the block, which are different from values or data that were written to and stored by the block. As another example, the read errors may include an error response that indicates that the data stored by the block is unavailable. In such situations, one technique to remedy the read errors is to continue to retry reading the data from the block, which may include iteratively adjusting a read voltage that is used to read the data from the block until the data is successfully read from the block. In addition to the apparent issues with failures to read data from the block, the iterative retries with different voltages may lead to additional read latency, thus ultimately affecting the overall performance of the non-volatile memory device or a system that utilizes or integrates the non-volatile memory device.

As another example, during idle time, the non-volatile memory device may operate at a first temperature that is lower than a second temperature at which the non-volatile memory device was programmed to store the data. The difference between the first temperature and the second temperature may be referred to as “cross temperature.” The occurrence of a cross temperature may cause read errors when performing read operations in some situations, such as when using read voltages that are relatively too high in comparison to the actual temperature of the non-volatile memory device (e.g., when using default read voltages). Accordingly, the occurrence of a cross temperature may cause read errors, which may also be subject to a technique that includes iteratively attempting different voltages to properly read the data stored therein.

The iterative techniques described above may include using a read retry table, which may include several possible read voltages that may be used to attempt to perform the read operations. If using one read voltage in the read retry table causes a read error, the controller may use a next voltage in the read retry table, and may iteratively continue in this manner until the read operation is able to be performed correctly. As noted above, the successive retries may lead to increased latency and overall reduced performance.

Additionally, performing multiple read retries as described above may subject the non-volatile memory device to a “read disturb” condition, which may include portions of the block losing data or otherwise becoming corrupted. In other words, the read disturb condition may cause physical damage to the non-volatile memory device. Therefore, performing read operations without considering the temperature of the non-volatile memory device may increase read latency during the read operations, may decrease read performance, and may cause physical damage to the non-volatile memory device.

Implementations described herein avoid and/or rectify issues with performing read operations on a non-volatile memory device without considering a temperature of the non-volatile memory device (e.g., issues identified above). For example, implementations described herein automatically adjust read voltages to be used when reading data from the non-volatile memory device, based on monitoring a temperature of the non-volatile memory device. Implementations described herein are directed to storing information regarding appropriate read voltages for a virtual block (VB) for use during subsequent read operations on the VB, thereby reducing read latency and increasing read performance. As used herein, a “virtual block” may refer to a collection of blocks across multiple logical unit numbers (LUNs) of the SSD. In other words, a virtual block may refer to a collection of physical locations of one or more portions (of the non-volatile memory device) identified by multiple LUNs. A virtual block may also refer to a collection of physical locations of one or more non-volatile memory devices (of the SSD) identified by multiple LUNs. In this regard, while a single block may identify a single physical location, a virtual block may refer to multiple physical locations.

The temperature of the non-volatile memory device may be monitored on an ongoing basis (e.g., periodically, intermittently, on an event-driven basis, etc.). For example, the temperature of the non-volatile memory device may be checked during write operations and program operations, without limitation. For example, the temperature of the non-volatile memory device may be checked during the programming of an open VB (e.g., writing data to the VB) and/or during the performance of reliability read operations on the VB. A VB may include wordlines which may refer to cells, arrays, and/or bits, without limitation, of the physical blocks (of the VB) that can store data and that can be accessed in order to read the data stored therein. The physical blocks may be included in different dies. The dies may be associated with chip enable signals and associated with communication channels of the non-volatile memory device. An “open VB” may refer to a VB that has one or more empty or available wordlines. A wordline may be “empty” or “available” when the wordline is available to store data. Conversely, a “closed VB” may refer to a VB with all wordlines programmed (e.g., a VB with no “empty” or “available” wordlines).

In some implementations, one or more metrics and/or values, without limitation, may be computed based on monitoring the temperature of the non-volatile memory device on an ongoing basis. For example, a temperature profile of the VB may be computed based on the monitoring, which may include calculating a running average temperature of the non-volatile memory device. In this regard, a “temperature profile” of the VB may identify different temperatures associated with the data of the VB (of the non-volatile memory device) over different time windows. In other words, a “temperature profile” may refer to a data structure that stores information regarding different temperatures associated with the data of the VB over different time windows (or periods of time). For example, the data structure may store a first temperature in association with a first time window, a second temperature in association with a second time window, and so on. With respect to monitoring the temperature of the non-volatile memory device on an ongoing basis some situations, in some examples, the temperature of the non-volatile memory device (e.g., the VB) may be determined when a write operation is performed on the VB. The read voltages associated with the data of the VB may be determined and kept up to date based on the running average temperature (e.g., an average temperature over a rolling time window). In some examples, the read voltages may be determined by performing one or more read operations using different read voltages until the data is successfully, with the least number of possible bit error rate, obtained from a physical location that stores the data. In some implementations, some other value may be calculated in addition to or in lieu of the running average, such as a median temperature over a rolling time window, a minimum temperature over a rolling time window, a maximum temperature over a rolling time window, without limitation.

In some implementations, the read voltages may be updated after write operations initiated by a host device. For example, the read voltages may be updated based on a cross temperature, a temperature differential, a temperature change, without limitation. For instance, the read voltages may be updated based on a difference between a temperature during a write operation (also referred to as “program temperature”) and a temperature during a subsequent read operation (also referred to as “read temperature”). In some implementations, the most recently updated read voltages may be used to perform subsequent read operations on the non-volatile memory device.

Typically, loss of electrons may cause the degradation of data retention, which may cause threshold voltages to decrease. In other words, the threshold voltages are decreased due to the loss of electrons. Accordingly, when updating threshold voltages based on temperature profiling, the threshold voltages may be decreased by an amount that is based on the decrease of the threshold voltages cause by the loss of electrons. A mismatched read condition may occur if the threshold voltages are not reduced. For example, the mismatched read condition may occur if a read voltage (used to perform a read operation) is not reduced in accordance with the threshold voltages (which are reduced to account for the loss of electrons). Conversely, when updating threshold voltages based on cross temperature, the threshold voltages may be increased because cross temperature may cause threshold voltages to increase. For example, if the program temperature exceeds the read temperature, threshold voltages may be increased by an amount that is based on the difference between the program temperature and the read temperature. The most recent temperature of the VB may be used to determine a final read threshold voltage.

Implementations described herein provide a technical solution for dynamic read voltage adjustment based on factors such as temperature profiling and/or cross temperature. Dynamically adjusting read voltages in this manner will significantly improve read latency, reduce read errors, and mitigate physical damage to the non-volatile memory device (e.g., alleviate potential issues with techniques described above).

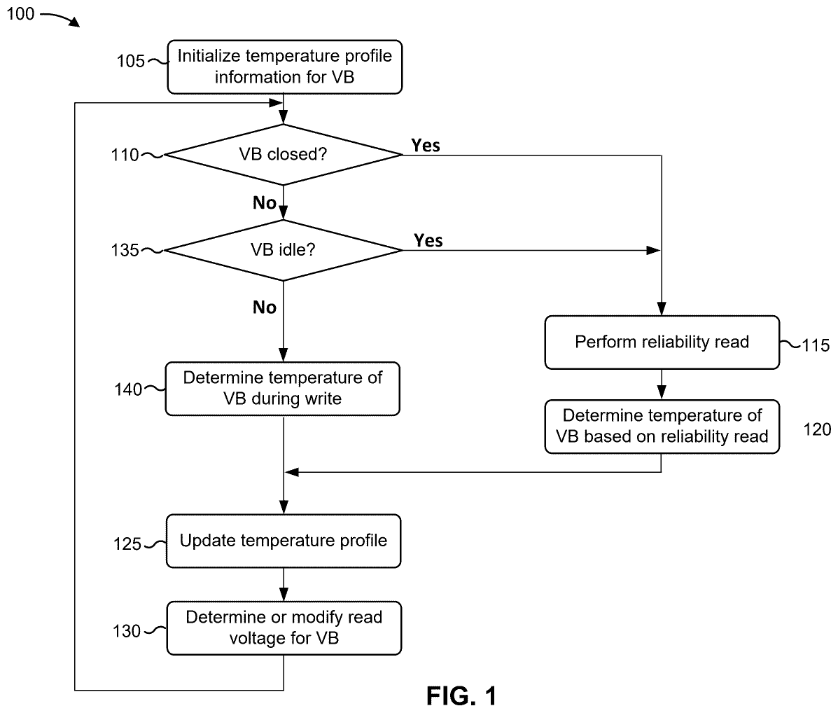

FIG. 1 is a diagram of an example process 100 of dynamic read voltage adjustment for a non-volatile memory device as described herein. In some implementations, the dynamic read voltage adjustment may be performed with respect to one or more VBs of the non-volatile memory device. The operations described in connection with example process 100 may be performed by one or more of a controller (e.g., of a non-volatile memory device), a host device, and/or some other suitable device or system. Although examples are described in the context of an SSD or a NAND flash memory device, the same concepts may apply to other types of storage devices, and the described aspects and examples are therefore interchangeable with respect to such other types of storage devices.

As shown in FIG. 1, process 100 may begin with a particular VB of a non-volatile memory device being in an initial state, in which the VB is open. A temperature profile of the VB may be reset, initialized, and/or otherwise set to an initial state, such as a blank profile or a default profile, without limitation. (at block 105). As discussed above, the temperature profile information may indicate different temperatures of the VB over a period of time (e.g., different temperatures of the non-volatile memory device over a lifetime of the data in the VB or a running average temperature of the VB over a rolling time window, without limitation.). In some situations, the temperature of the VB may be determined when a write operation is performed on the VB. In some implementations, the controller of the non-volatile memory device may update the temperature profile of the VB based on one or more events, such as during or after a write operation (e.g., an initial write operation, or a first write operation, without limitation.). Updating the temperature profile information may include indicating a time at which the temperature was determined. The temperature of the VB may include a temperature of a collection of physical blocks (e.g., as reported by the non-volatile memory device and/or the controller of the non-volatile memory device), a temperature of the non-volatile memory device that includes the collection of physical blocks, or a temperature of an SSD that includes the non-volatile memory device.

The temperature may be determined using one or more temperature sensor devices included on the SSD. Alternatively, the temperature may be determined using one or more temperature sensor devices external to the SSD, such as thermal cameras, thermocouples, among other examples. Alternatively, the temperature may be determined using software, such as simulation software, heat transfer modeling, among other examples. The sensors and software, without limitation, may report the temperature on a VB-basis, which may include performing a mapping or correlation of physical elements of the non-volatile memory device (e.g., physical blocks) to virtual elements (e.g., VBs).

In some implementations, the controller may store and update VB information regarding the VB. The VB information may include a data structure (e.g., a table) that stores information regarding the VB. For example, the VB information may store information indicating whether the VB is an open VB or a closed VB. Additionally, or alternatively, the VB information may store information indicating whether the VB stores information for a host device. Additionally, or alternatively, the VB information may store information indicating whether the VB is scheduled for a garbage collection operation. In some examples, the VB information may include a running average temperature of the VB until a last time the VB was accessed (e.g., by way of a write operation or a reliability read operation), a temperature of the VB when a last wordline was written (e.g., a most recently written wordline and/or a sequentially last wordline of the VB), a read voltage determined based on a temperature of the VB, and a time when a running average temperature was calculated. The temperature of the VB may refer to a temperature of the VB when the VB is last programmed. The temperature of the VB may include a temperature of physical blocks of the VB. In some implementations, the temperature of the VB may be used to determine the read voltage.

In some implementations, the read voltage (determined based on the temperature) may be used to perform a first read operation on the VB instead of using a default read voltage). Using the read voltage may mitigate or prevent read errors resulting from using the default read voltage as described herein. In some examples, the VB information may include information regarding different temperatures, corresponding times when the temperatures were determined, and average temperature over different periods of time. In some implementations, the VB information may be stored in a data structure, referred to a VB information table, which may include information described above such as a running average temperature (e.g., a running average temperature since a last access of the VB such as a write or read access), a temperature when the last wordline was written to the VB, without limitation.

The controller may, after initializing the temperature profile information, update the temperature profile for the VB on an ongoing basis. Updating the temperature profile may include determining whether the VB is closed (at block 110). For example, if the controller determines that all wordlines of the VB have been programmed, the controller may determine that the VB is closed. If the controller determines that the VB is closed (at block 110—YES), read voltages with extra VB information may be updated as part of reliability reads, as discussed below. For example, the read voltage of the VB will be recorded. The extra VB information may include a temperature of the VB, As explained herein, the temperature of the VB may include a temperature of physical blocks of the VB. In some examples, the controller may perform one or more reliability reads, also referred to as “reliability read” operations or “read refresh” operations (at block 115). For example, the one or more reliability reads may be performed to determine whether the VB may be subjected to data corruption or data loss, and may be initiated without receiving a request (e.g., from an external device) to read the VB. In other words, the reliability reads may be performed to ensure the reliability and integrity of data stored in the VB. In some examples, the controller may perform the one or more reliability reads periodically (e.g., every ten seconds, thirty seconds, minute, three minutes, among other examples), and/or on some other suitable basis. The controller may perform the one or more reliability reads on the blocks of the collection of blocks.

Additionally to performing the reliability read/s, the controller may determine a temperature of the VB based on a temperature at the time the reliability read is performed (at block 120). The controller may update (at block 125) the temperature profile information to indicate the temperature (determined at 120) and a time when the temperature was determined. Additionally, the controller may determine an amount of time elapsed since a previous reliability read or since a previous temperature of the VB was determined. In some situations, the controller may store information regarding the temperature at the time of the reliability read, the time of the reliability read and/or of the temperature reading, and the amount of time elapsed since the last reliability read or the previous temperature in the VB information table.

In some situations, the controller may determine, modify, or update, without limitation, a read voltage for performing a read operation on the VB (at block 130). The controller may, for example, determine the read voltage based on an average temperature of the VB over a period of time, as indicated by information included in the VB information table. As an example, the controller may determine the average temperature using a first temperature and a second temperature in the temperature profile (e.g., where such temperatures are determined at different times). Alternatively, the controller may determine some other value that is based on a mathematical formula that takes as inputs the first temperature and the second temperature.

In some implementations, the controller may determine an amount of data retention degradation based on the average temperature. In some implementations, the controller may determine the amount of data retention degradation based on the average temperature and the period of time. In some examples, the amount of data retention degradation may be determined based on a shift in the threshold voltages. For example, the threshold voltages may be decreased due to loss of electrons. The shift of the threshold voltages may lead to a shift of an optimum read voltage. For example, the optimum read voltage may be decreased. The read voltage may be periodically monitored and recorded, for reference. For example, the read voltage may be included in the VB information for the VB. In some situations, the amount of data retention shift (e.g., the shift in the threshold voltages) will depend on two factors: a) the running temperature of the VB after the VB is programmed and b) the time delay between read and program operations. In some examples, the shift of the threshold voltages may be a function that is based on the running/average temperature of the VB and the delay between program and read operations. The running temperature profiling per VB basis may be provided. Based on the amount of data retention degradation, the controller may determine the read voltage for performing subsequent read operations on the VB. In some examples, the controller may determine the read voltage by adjusting a previously determined read voltage. For example, the controller may decrease the previously determined read voltage by an amount that is based on the amount of data retention degradation. The controller may store information regarding the determined read voltage in the VB information.

If, on the other hand, the controller determines that the VB is not closed (at block 110—NO), the controller may determine whether the VB is idle (at block 135). The controller may determine that the VB is idle by determining that the VB has not be subjected to write operations since a particular period of time. If the controller determines that the VB is idle, read voltages with extra VB information may be updated as part of reliability reads (e.g., as discussed above with respect to blocks 115 through 130).

If the controller determines that the VB is not idle (at block 135—NO), read voltages may be updated for subsequent reads on a per-VB basis based on VB write operations, as discussed below. That is, since the VB is not idle and is not closed, this may indicate that write operations are being performed on the VB. During the write operations, the controller may determine an updated read voltage for subsequent read operations on the VB. For instance, the controller may determine a current temperature of the VB during a write operation (at block 140). In some implementations, the controller may further determine a time at which the current temperature was determined (e.g., coinciding with the write operation). The controller may determine an average temperature based on the current temperature and a previous temperature determined during a previous write operation. In some implementations, the previous temperature may be a temperature determined during the previous write operation. In some implementations, the previous temperature may be determined during a time when a write operation is not being performed. For example, the temperature may be measured via a command sequence (e.g., a series of command sent to the non-volatile memory device). The controller may determine a period of time elapsed since the previous temperature was determined or since the previous write operation. As similarly noted above, the controller may update the temperature profile associated with the VB based on the temperature determined during the write (at block 140), which may include updating the average temperature in the VB information table or adding an entry for the temperature determined during the write operation, without limitation.

Additionally, as also discussed above, the controller may determine an updated read voltage for performing read operations on the VB, as described herein (e.g., based on a measure of data retention degradation and/or other suitable factors). The controller may update the VB information table to indicate the updated read voltage, the average temperature, and a running average temperature of the VB.

Although FIG. 1 shows example blocks of process 100, in some implementations, process 100 may include additional blocks, fewer blocks, different blocks, or differently arranged blocks than those depicted in FIG. 1. Additionally, or alternatively, two or more of the blocks of process 100 may be performed in parallel. Further, some or all of the operations of process 100 may be repeated and/or performed iteratively (e.g., on an ongoing basis) in order to keep the temperature profile and read voltage for the VB up-to-date.

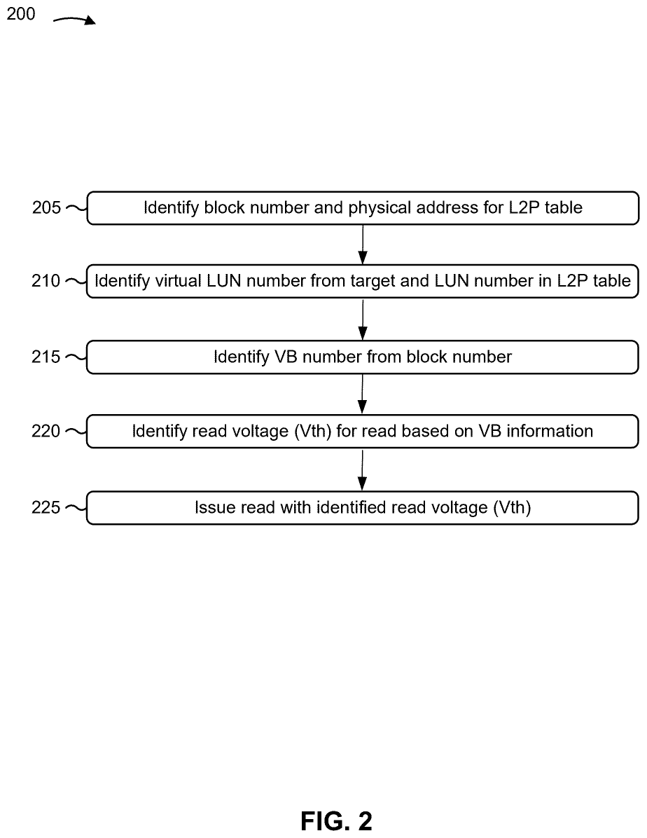

FIG. 2 is a diagram of an example process 200 of using a read voltage for a VB (e.g., based on a VB information table, as discussed above). The operations described in connection with example process 200 may be performed by one or more of a controller (e.g., of a non-volatile memory device), a host device, and/or some other suitable device or system. Although examples are described in the context of an SSD or a NAND flash memory device, the same concepts may apply to other types of storage devices, and the described aspects and examples are therefore interchangeable with respect to such other types of storage devices.

As shown in FIG. 2, the controller may identify a block number and a physical address from a logical to physical (L2P) table (at block 205). The controller may identify a virtual logical unit number (LUN) number from target and a LUN number in the L2P table (at block 210). The controller may identify a VB number from the block number (at block 215). The controller may identify a read voltage (Vth) for a read operation based on the VB information (at block 220). As discussed above, the read voltage may have been determined based on a temperature profile associated with the VB (e.g., as discussed above with respect to blocks 125 and/or 130). The controller may further cause a read operation to be performed using the identified read voltage. For example, the controller may issue a read command with the identified read voltage (Vth) (at block 225). In other words, the controller may perform a read operation with the identified read voltage (Vth).

In some situations, the read operation may be successful based on the identified read voltage, and the controller may generate or output a notification indicating the successful read. However, in other situations, the read operation may not be successful. For example, in some situations, a temporary temperature spike or other type of occurrence may cause the read operation to fail.

Although FIG. 2 shows example blocks of process 200, in some implementations, process 200 may include additional blocks, fewer blocks, different blocks, or differently arranged blocks than those depicted in FIG. 2. Additionally, or alternatively, multiple blocks of process 200 may be performed in parallel.

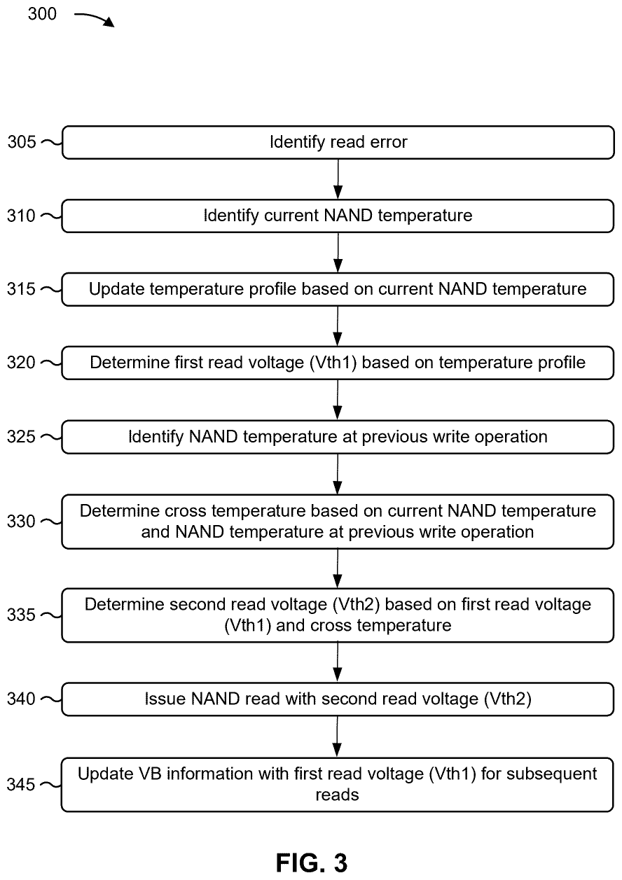

FIG. 3 illustrates an example process 300 for further adjusting a read voltage in such situations, in order to read data from a given VB. The operations described in connection with example process 300 may be performed by one or more of a controller (e.g., of a non-volatile memory device), a host device, and/or some other suitable device or system. Although examples are described in the context of an SSD or a NAND flash memory device, the same concepts may apply to other types of storage devices, and the described aspects and examples are therefore interchangeable with respect to such other types of storage devices.

As noted above, the controller may identify a read error (at block 305). For example, as explained above in connection with block 225, a read operation may not be successful. In this regard, the controller may identify a read error with respect to the read operation issued to a given VB. In accordance with some implementations, the controller may identify a current NAND temperature (at block 310). For example, the controller may identify a current temperature associated with the VB. The controller may update temperature profile based on the current NAND temperature (at block 315). For example, as similarly discussed above in connection with block 125, the controller may update a temperature profile based on the current temperature, which may include determining a running average temperature based on the current temperature and previously measured temperatures associated with the VB.

The controller may further determine a first read voltage (Vth1) based on the temperature profile (at block 320). For example, as similarly discussed above, the first read voltage may be associated with a moving average temperature that includes the current temperature (as measured at block 310) as well as one or more previous temperature readings. In some implementations, the controller may determine the first read voltage Vth1 for the VB further based on an amount of time elapsed since a previous reliability read, since a previous temperature was determined, or since a previous temperature of the VB was determined. In some implementations, determining the first read voltage Vth1 may further be based on a previous read voltage that was previously determined for the VB. For example, the first read voltage Vth1 may be determined based on adjusting the previous read voltage, where such adjustment is based on the updated temperature profile of the VB (e.g., based on the updated average temperature).

From the VB information, the controller may identify a NAND temperature at a previous write operation (at block 325), as similarly discussed above in connection with block 140. The previous write operation may refer, for example, to the last wordline written to the VB.

At block 330, the controller may further determine a cross temperature based on the current NAND temperature (identified at block 310) and the temperature at the previous write operation (identified at block 325). This cross temperature may, as noted above, refer to a differential between temperatures of the VB during the current read operation and during an immediately preceding write operation. In other words, the cross temperature may be a difference between a program temperature and a read temperature. This temperature differential may be relatively temporary in nature, as the temperature during the write operation may result in a temperature spike that quickly dissipates, but in some scenarios may not dissipate before a following read operation occurs, thus resulting in a read error (e.g., as identified at block 305, in this example). For instance, the temperature spike may cause the current read voltage, associated with the VB information table and as determined based on a moving average temperature of the VB, to be insufficient or otherwise incorrect (e.g., in the context of the temperature spike, which would be higher than the moving average temperature).

Accordingly, in accordance with some implementations, the controller may determine a second read voltage (Vth2) based on the first read voltage Vth1 and the cross temperature (at block 335). For example, the controller may determine an adjustment to the first read voltage Vth1 based on the determined cross temperature, and/or may otherwise determine the second read voltage Vth2 based on the cross temperature. In some embodiments, the controller may determine the second read voltage Vth2, or the adjustment to the first read voltage Vth1, based on a difference between the current NAND temperature (identified at block 310) and the moving average temperature. In some implementations, the controller may determine the second read voltage Vth2, or the adjustment to the first read voltage Vth1, in some other manner that is based on the determined cross temperature and/or some other factor.

The controller may further cause a read operation to be performed using the identified second read voltage Vth2. For example, the controller may issue NAND read with second read voltage (Vth2) (at block 340). This read operation may be more likely to succeed than the initial read operation (e.g., which resulted in the error identified at block 305), as this read operation accounts for temperature differences that may have occurred due to a preceding write operation to the same VB.

The controller may further update the VB information using the first read voltage Vth1 for subsequent reads (at block 345). For example, while the second read voltage Vth2 may have been applicable for the current read (performed at block 340), the second read voltage Vth2 may no longer be necessary for subsequent reads (e.g., subsequent read operations), as the temperature of the VB may have returned to nominal levels by such time (e.g., because the cross temperature is a temporary effect).

The controller may further provide a read request completion notification. For example, a notification may be provided that the read operation is successful. In situations where the read operation is not successful (at block 340), the controller may proceed to deep error recovery and/or may perform other types of operations.

Although FIG. 3 shows example blocks of process 200, in some implementations, process 300 may include additional blocks, fewer blocks, different blocks, or differently arranged blocks than those depicted in FIG. 3. Additionally, or alternatively, multiple blocks of process 300 may be performed in parallel.

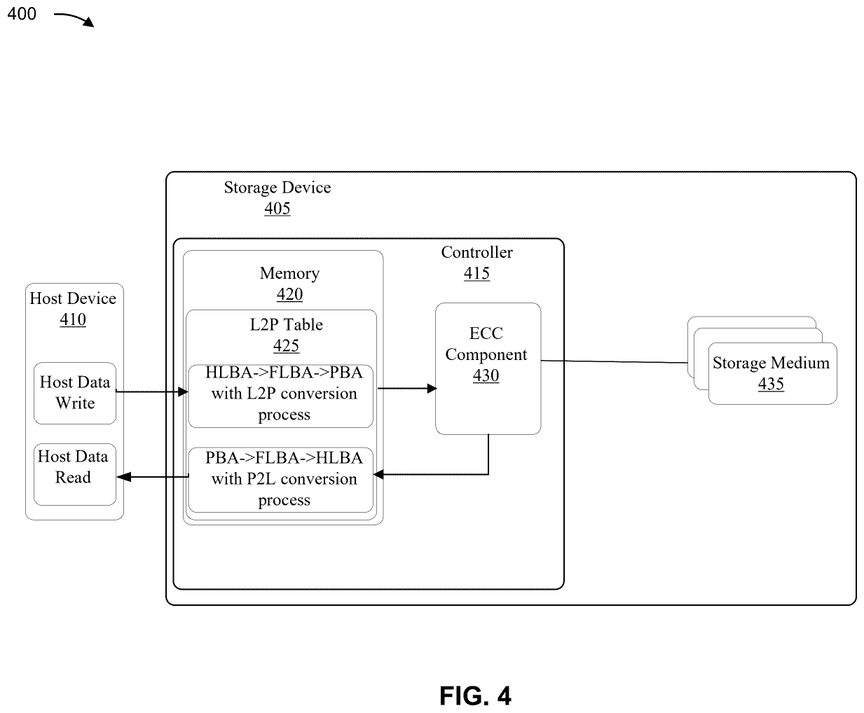

FIG. 4 is a diagram of an example 400 of a device generating logical to physical (L2P) addresses. Example 400 describes components and operations associated with a storage device 405. In some implementations, storage device 405 may include a solid state drive (SSD). As shown in FIG. 4, storage device 405 may be associated with a host device 410. Host device 410 may access data (also referred to as “host data”) stored by storage device 405. For example, as shown in FIG. 4, host device 410 may initiate a host data write operation (e.g., a write operation) to write the host data to storage device 405 (e.g., to store the data on storage device 405) and may initiate a host read operation (e.g., a read operation) to read the host data from storage device 405.

Host device 410 may include one or more devices capable of receiving, generating, storing, processing, and/or providing information associated with generating an L2P data structure (or L2P table), as described elsewhere herein. The host device 410 may include a communication device and a computing device. For example, the host device 410 may include a wireless communication device, a mobile phone, a user equipment, a laptop computer, a tablet computer, a desktop computer, a wearable communication device (e.g., a smart wristwatch, a pair of smart eyeglasses, a head mounted display, or a virtual reality headset), or a similar type of device.

As shown in FIG. 4, storage device 405 may include a controller 415. Controller 415 may include one or more of an application specific integrated circuit (ASIC) or firmware. Controller 415 may cause functions to be performed on storage device 405, such as read operations, write operations, erase operations, garbage collection operations, among other examples. Controller 415 may include a memory 420 and an error correction code (ECC) component 430. Memory 420 may include a RAM (e.g., dynamic random access memory (DRAM), a synchronous DRAM (SDRAM), among other examples).

As shown in FIG. 4, memory 420 may include an L2P table 425 (or an L2P data structure). L2P table 425 may store a mapping between host logical block addresses (or logical addresses identified by host device 410) and physical block addresses (or physical addresses of non-volatile memory devices of storage device 405). In some implementations, L2P table 425 may be generated by controller 415.

In some implementations, controller 415 may identify a host logical block address

(HLBA) associated with the host data by which host device 410 may reference the host data in a future read operation. As shown in FIG. 4, controller 415 may convert the HLBA to a flash logical block address (FLBA) or other local logical block address, and then may link the FLBA to a physical block address (PBA) using an L2P conversion process. The L2P conversion process may refer to a process for converting addresses between physical block addresses and logical block addresses. Conversely, controller 415 may convert a PBA to an FLBA or other local logical block address, and then may link the FLBA to an HLBA using a physical to logical process. In this way, the host device 410 may send a static address associated with the host data, controller 415 may link the address known to host device 410 to an address known to storage device 405 (the FLBA), and may link the address known to storage device 405 to a physical address of the host data within a storage medium of storage device 405.

Controller 415 may store the links between the HLBA, the FLBA, and the PBA in L2P table 425. In some aspects, the host data may be moved within the storage medium or between storage mediums of storage device 405, which controller 415 may note in the link between the FLBA and the physical location. In this way, the HLBA may bypass being updated when the host data is moved to a new PBA.

ECC component 430 may include an ECC engine. ECC component 430 may perform error correction code encoding on the host data. In some implementations, the error correction code encoding may include adding redundancy, parity bits, or other information that can later be used to identify errors in the host data when read from the storage medium. Controller 415 may provide the host data, after encoding, via flash control channels (not shown) to write on storage mediums of storage device 405.

As shown in FIG. 4, storage device 405 may include storage mediums 435 (individually “storage medium 435” and collectively “storage mediums 435”). A storage medium 435 may include a non-volatile memory device. For example, the storage medium 435 may include a NAND memory device.

As indicated above, FIG. 4 is provided as an example. Other examples may differ from what is described with regard to FIG. 4. The number and arrangement of devices shown in FIG. 4 are provided as an example. In practice, there may be additional devices, fewer devices, different devices, or differently arranged devices than those shown in FIG. 4. Furthermore, two or more devices shown in FIG. 4 may be implemented within a single device, or a single device shown in FIG. 4 may be implemented as multiple, distributed devices. Additionally, or alternatively, a set of devices (e.g., one or more devices) shown in FIG. 4 may perform one or more functions described as being performed by another set of devices shown in FIG. 4.

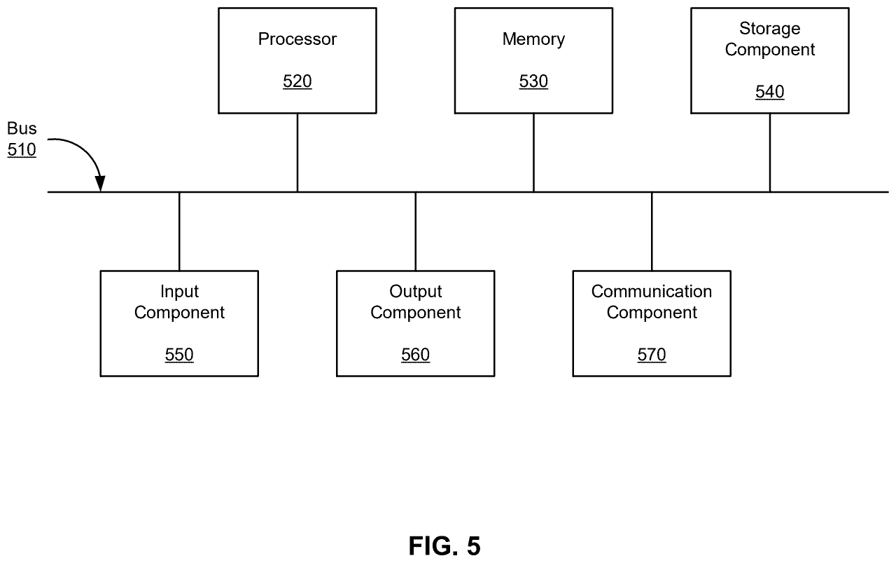

FIG. 5 is a diagram of example components of a device 500, which may correspond to one or more devices of FIG. 3, such as a controller or a host device. In some implementations, the controller or the host device may include one or more devices 500 and one or more components of device 500. As shown in FIG. 5, device 500 may include a bus 510, a processor 520, a memory 530, a storage component 540, an input component 550, an output component 560, and a communication component 570.

Bus 510 includes a component that enables wired or wireless communication among the components of device 500. Processor 520 includes a central processing unit, a graphics processing unit, a microprocessor, a controller, a microcontroller, a digital signal processor, a field-programmable gate array, an application-specific integrated circuit, or another type of processing component. Processor 520 is implemented in hardware, firmware, or a combination of hardware and software. In some implementations, processor 520 includes one or more processors capable of being programmed to perform a function. Memory 530 includes a random access memory, a read only memory, or another type of memory (e.g., a flash memory, a magnetic memory, or an optical memory).

Storage component 540 stores information or software related to the operation of device 500. For example, storage component 540 may include a hard disk drive, a magnetic disk drive, an optical disk drive, a solid state disk drive, a compact disc, a digital versatile disc, or another type of non-transitory computer-readable medium. Input component 550 enables device 500 to receive input, such as user input or sensed inputs. For example, input component 550 may include a touch screen, a keyboard, a keypad, a mouse, a button, a microphone, a switch, a sensor, a global positioning system component, an accelerometer, a gyroscope, or an actuator. Output component 560 enables device 500 to provide output, such as via a display, a speaker, or one or more light-emitting diodes. Communication component 570 enables device 500 to communicate with other devices, such as via a wired connection or a wireless connection. For example, communication component 570 may include a receiver, a transmitter, a transceiver, a modem, a network interface card, or an antenna.

Device 500 may perform one or more processes described herein. For example, a non-transitory computer-readable medium (e.g., memory 530 or storage component 540) may store a set of instructions (e.g., one or more instructions, code, software code, or program code) for execution by processor 520. Processor 520 may execute the set of instructions to perform one or more processes described herein. In some implementations, execution of the set of instructions, by one or more processors 520, causes the one or more processors 520 or the device 500 to perform one or more processes described herein. In some implementations, hardwired circuitry may be used instead of or in combination with the instructions to perform one or more processes described herein. Thus, implementations described herein are not limited to any specific combination of hardware circuitry and software.

The number and arrangement of components shown in FIG. 5 are provided as an example. Device 500 may include additional components, fewer components, different components, or differently arranged components than those shown in FIG. 5. Additionally, or alternatively, a set of components (e.g., one or more components) of device 500 may perform one or more functions described as being performed by another set of components of device 500.

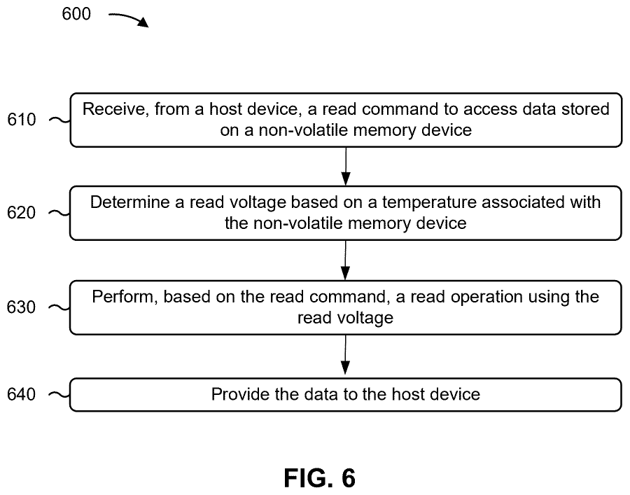

FIG. 6 is a flowchart of an example process 600 associated with determining read voltage based on temperature of a non-volatile memory device, as described herein. In some implementations, one or more process blocks of FIG. 6 may be performed by a controller (e.g., controller 415). Additionally, or alternatively, one or more process blocks of FIG. 6 may be performed by one or more components of device 500, such as processor 520, memory 530, storage component 540, input component 550, output component 560, and/or communication interface 570.

As shown in FIG. 6, process 600 may include receiving, from a host device, a read command to access data stored on a non-volatile memory device (block 610). For example, the controller may receive, from a host device, a read command to access data stored on a non-volatile memory device, as described above in connection with the host read operation in FIG. 4.

As further shown in FIG. 6, process 600 may include determining a read voltage based on a temperature associated with the non-volatile memory device (block 620). For example, the controller may determine a read voltage based on a temperature associated with the non-volatile memory device, as described above in connection with FIG. 1 (e.g., block 130).

As further shown in FIG. 6, process 600 may include performing, based on the read command, a read operation using the read voltage to access the data (block 630). For example, the controller may perform, based on the read command, a read operation using the read voltage to access the data, as described above in connection with FIG. 2 (e.g., block 225).

As further shown in FIG. 6, process 600 may include providing the data to the host device (block 640). For example, the controller may provide the data to the host device, as described above in connection with FIG. 4.

In some implementations, determining the read voltage comprise determining the read voltage based on an average temperature associated with the non-volatile memory device, wherein the average temperature is based on a first temperature associated with a first read and a second temperature performing reliability reads.

In some implementations, determining the read voltage comprise adjusting a default read voltage, associated with the non-volatile memory device, based on the average temperature.

In some implementations, determining the read voltage comprise determining the read voltage based on a change between a program temperature and a read temperature.

In some implementations, determining the read voltage comprise adjusting a default read voltage, associated with the non-volatile memory device, based on the change between the program temperature and the read temperature.

In some implementations, the temperature includes a temperature associated with the data in a virtual block.

In some implementations, process 600 includes periodically updating the temperature associated with the non-volatile memory device.

Although FIG. 6 shows example blocks of process 600, in some implementations, process 600 may include additional blocks, fewer blocks, different blocks, or differently arranged blocks than those depicted in FIG. 6. Additionally, or alternatively, two or more of the blocks of process 600 may be performed in parallel.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

In some implementations, a method comprising: receiving, from a host device, a read command to access data stored on a non-volatile memory device; determining a read voltage based on a temperature associated with the non-volatile memory device; performing, based on the read command, a read operation using the read voltage to access the data; and providing the data to the host device.

In some implementations, a system comprising: a controller, of a non-volatile memory device, to: determine a temperature associated with the non-volatile memory device; determine, based on the temperature, a read voltage for accessing data stored by the non-volatile memory device; and perform a read operation, using the read voltage, to access the data.

In some implementations, a computer program product comprising: one or more computer readable storage media, and program instructions collectively stored on the one or more computer readable storage media, the program instructions comprising: program instructions to determine a temperature associated with a portion of the non-volatile memory device; program instructions to determine, based on the temperature, a read voltage for accessing data stored by the non-volatile memory device; and program instructions to perform a read operation, using the read voltage, to access the data.

As used herein, the term “component” is intended to be broadly construed as hardware, firmware, or a combination of hardware and software. It will be apparent that systems or methods described herein may be implemented in different forms of hardware, firmware, or a combination of hardware and software. The actual control hardware or software code used to implement these systems or methods is not limiting of the implementations. Thus, the operation and behavior of the systems or methods are described herein without reference to specific software code—it being understood that software and hardware can be used to implement the systems or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims or disclosed in the specification, these combinations are not intended to limit the disclosure of various implementations. In fact, many of these features may be combined in ways not specifically recited in the claims or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein is to be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “or.” unless explicitly stated otherwise (e.g., if used in combination with “either” or “only one of”).

What is claimed is:

1. A method comprising:
receiving, from a host device, a read command to access data stored on a non-volatile memory device;
determining a read voltage based on a temperature associated with the non-volatile memory device;
performing, based on the read command, a read operation using the read voltage to access the data; and
providing the data to the host device.

2. The method of claim 1, wherein determining the read voltage comprise:
determining the read voltage based on an average temperature associated with the non-volatile memory device,
wherein the average temperature is based on a first temperature associated with a first read and a second temperature performing reliability reads.

3. The method of claim 2, wherein determining the read voltage comprise:
adjusting a default read voltage, associated with the non-volatile memory device, based on the average temperature.

4. The method of claim 1, wherein determining the read voltage comprise:
determining the read voltage based on a change between a program temperature and a read temperature.

5. The method of claim 4, wherein determining the read voltage comprise:
adjusting a default read voltage, associated with the non-volatile memory device, based on the change between the program temperature and the read temperature.

6. The method of claim 1, wherein the temperature includes a temperature associated with the data in a virtual block.

7. The method of claim 1, comprising:
periodically updating the temperature associated with the non-volatile memory device.

8. A system comprising:
a controller, of a non-volatile memory device, to:
determine a temperature associated with the non-volatile memory device;
determine, based on the temperature, a read voltage for accessing data stored by the non-volatile memory device; and
perform a read operation, using the read voltage, to access the data.

9. The system of claim 8, wherein, to determine the temperature, the controller is to:
determine the temperature based on an average temperature of the non-volatile memory device since the data was written to a virtual block of the non-volatile memory device.

10. The system of claim 9, wherein the read operation is a first read operation and the read voltage is a first read voltage, and
wherein the controller is to:
determine that the first read operation is unsuccessful; and
determine a second read voltage based on a change between a program temperature and a read temperature; and
perform a second read operation using the second read voltage.

11. The system of claim 10, wherein, to determine the second read voltage, the controller is to:
adjust the first read voltage based on the change between the program temperature and the read temperature.

12. The system of claim 10, wherein the controller is to:
determine that the second read operation is successful; and
store information regarding the second read voltage.

13. The system of claim 10, wherein the temperature includes a temperature associated with a portion of the non-volatile memory device.

14. The system of claim 10, wherein the temperature includes a temperature of the non-volatile memory device taken when a virtual block of the non-volatile memory device was written.

15. A computer program product comprising:
one or more computer readable storage media, and program instructions collectively stored on the one or more computer readable storage media, the program instructions comprising:
program instructions to determine a temperature associated with a non-volatile memory device when a portion of the non-volatile memory device was written;
program instructions to determine, based on the temperature, a read voltage for accessing data stored by the non-volatile memory device; and
program instructions to perform a read operation, using the read voltage, to access the data.

16. The computer program product of claim 15, wherein the portion includes a virtual block.

17. The computer program product of claim 16, wherein the program instructions to determine the read voltage comprise:
program instructions to determine the temperature based on an average temperature of the non-volatile memory device associated with the data in the portion of the non-volatile memory device measured since the data was written to the virtual block.

18. The computer program product of claim 17, wherein the program instructions to determine the read voltage comprise:
adjust a default read voltage based on the average temperature.

19. The computer program product of claim 15, wherein the program instructions to determine the read voltage comprise:
program instructions to determine the temperature based on a change between a program temperature and a read temperature,
wherein the program instructions to determine the read voltage comprise:
program instructions to adjust a default read voltage based on the change between the program temperature and the read temperature.

20. The computer program product of claim 15, wherein the program instructions comprise:
program instructions to periodically update the temperature associated with the data on the portion of the non-volatile memory device; or
program instructions to update the temperature associated with the data on the portion of the non-volatile memory device based on performing the read operation.
